(19) United States
(12) Patent Application Publication
(10) Pub. No.: US 2008/0112580 A1
(43) Pub. Date: May 15, 2008

(54) WATER BOTTLE AMPLIFIER UNIT FOR A BICYCLE AUDIO SYSTEM

(76) Inventor: Edward M. Files, Lee's Summit, MO (US)

Correspondence Address: JACQUELINE E. HARTT, PH.D;ALLEN, DYER, DOPPELT, MILBRATH & GILCHRIST, P.A., P.O. BOX 3791, ORLANDO, FL, 32802-3791, US

(21) Appl. No.: 11/559,400

(22) Filed: Nov. 13, 2006

(51) Int. Cl. H03F 21/00

(52) U.S. Cl. 381/120

(57) ABSTRACT

An audio amplifier unit for a bicycle audio system includes audio amplifier circuitry and a rechargeable battery powering the audio amplifier circuitry which are housed in a weather resistant housing sized to be received and retained within a bicycle water bottle holder. Electrical connections are provided for connecting the amplifier circuitry to a personal audio device and at least one external speaker.

### BACKGROUND OF THE INVENTION

1. Field of the Invention

This invention relates to audio systems for use on bicycles, and in particular to a battery powered audio amplifier unit for such an audio system which is sized and shaped to fit in the water bottle holder of a bicycle.

2. Description of the Related Art

It is common practice for bicyclists to listen to music while riding. This is often done using a personal audio device such as a portable compact disc or tape player, a radio, a satellite radio, an mp3 player (such as an ipod®), or the like. These devices are normally carried on the user's person (such as in a pocket or clipped to a belt) and equipped with headphones through which the user listens to music. A problem with listening to such devices while riding is that the use of headphones tends to blocks other sounds and makes it difficult for the bicyclist to hear approaching automobile traffic and other safety hazards.

A solution to this problem would be to provide speakers mounted on the bicycle through which a rider could hear music from a personal audio player. This would allow the bicyclist to hear music from the personal audio player while not blocking his or her ears and preventing reception of other sounds. Personal audio players, however, do not typically produce enough power to drive speakers larger than those found in standard headphones. In order to use larger speakers, an audio amplifier must be connected between the personal audio device and the speakers. An amplifier requires a power source.

Power sources have been previously mounted on bicycles for operating lighting systems for riding at night. These include generators driven by one of the bicycle's wheels and various types of batteries. Batteries are often mounted inside the same housing as the light source. Some batteries for lighting systems have been sized and shaped so as to resemble a water bottle and to fit into a standard water bottle holder or “water bottle cage” provided on many bicycles. For example, Nite Rider Technical Lighting Systems of San Diego, Calif. manufactures and sells rechargeable water bottle batteries for use with its lighting systems. A water bottle battery similar to those known for use with lighting systems could be used to power an audio amplifier, however there still remain the problems of mounting an amplifier on the bicycle, protecting the amplifier from the elements, and providing electrical connections to the speakers, personal audio device, and battery.

If an audio amplifier is to be mounted on a bicycle, it needs to be protected from the elements in a weatherproof housing. It needs to be securely connected to the bicycle so that it does not work loose and/or become lost while riding, however it is preferably easily removable so that when a rider leaves his or her bicycle, the amplifier (as well as other components of the audio system) can be taken along and not left at risk to thievery. The electric connections from the amplifier to the speakers, personal audio device and battery need to either remain attached as the system is removed from the bicycle, or need to be easily reconnected so that reinstallation of the system on the bicycle is not overly complicated or time-consuming.

### SUMMARY OF THE INVENTION

The present invention comprises an audio amplifier unit for a bicycle audio system. The unit includes audio amplifier circuitry and a rechargeable battery powering the audio amplifier circuitry which are housed in a weather resistant housing sized to be received and retained within a bicycle water bottle holder. Electrical connections are provided for connecting the amplifier circuitry to a personal audio device and at least one external speaker.

### BRIEF DESCRIPTION OF THE DRAWINGS

FIG. 1 is a perspective view of a bicycle audio system including a water bottle amplifier unit according to the present invention with elements of the system shown mounted on a bicycle handlebar.

FIG. 2 is a perspective view of the water bottle amplifier unit of FIG. 1 showing the amplifier mounted in a water bottle holder located on a frame member of a bicycle.

FIG. 3 is exploded side elevational view of the water bottle amplifier unit.

FIG. 4. is a circuit diagram showing exemplary amplifier circuitry which may be included in the water bottle amplifier unit.

FIG. 5 is a circuit diagram showing audio signal processing circuitry for the water bottle amplifier unit.

### DETAILED DESCRIPTION OF THE PREFERRED EMBODIMENTS

As required, detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. The drawings constitute a part of this specification and include exemplary embodiments of the present invention and illustrate various objects and features thereof.

Certain terminology will be used in the following description for convenience in reference only and will not be limiting. For example, the words “upwardly,” “downwardly,” “rightwardly,” and “leftwardly” will refer to directions in the drawings to which reference is made. The words “inwardly” and “outwardly” will refer to directions toward and away from, respectively, the geometric center of the embodiment being described and designated parts thereof. Said terminology will include the words specifically mentioned, derivatives thereof and words of a similar import.

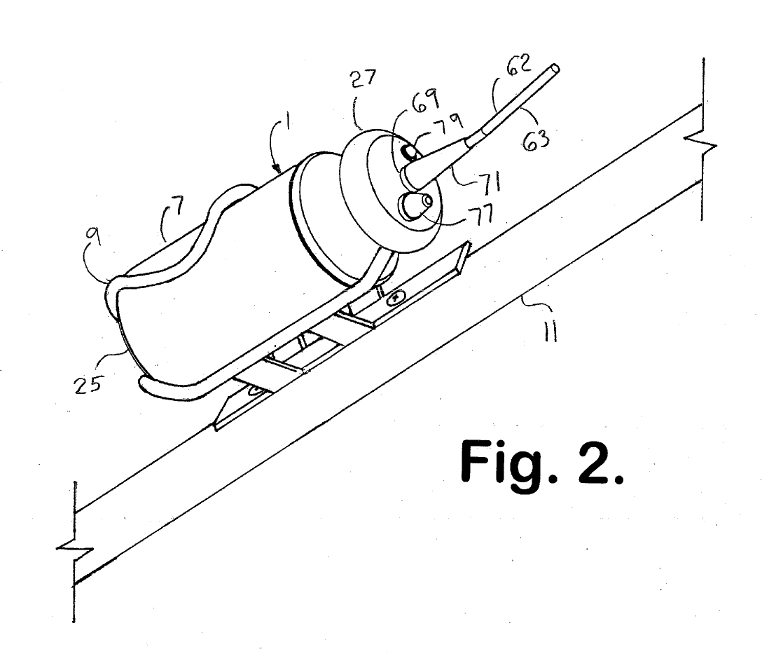

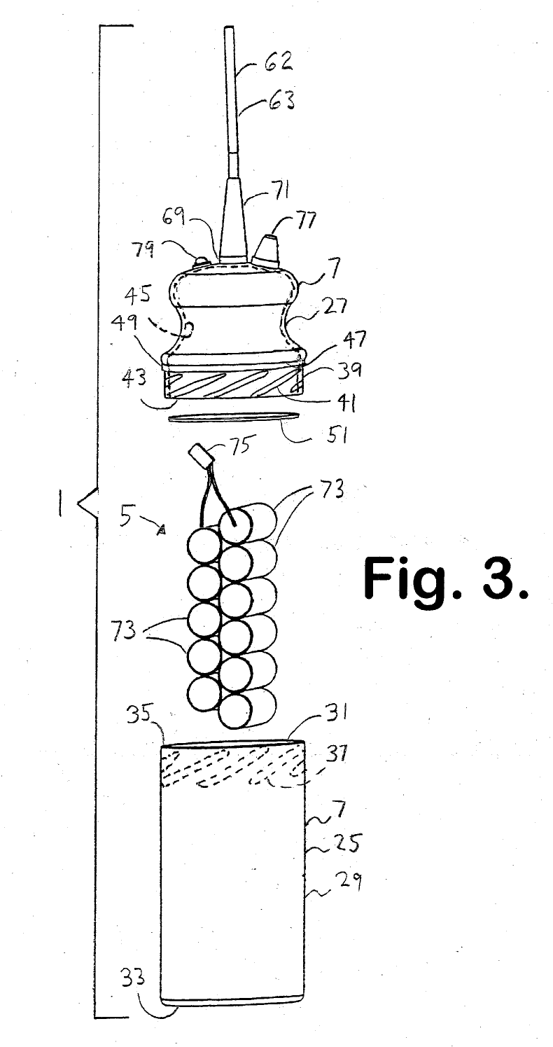

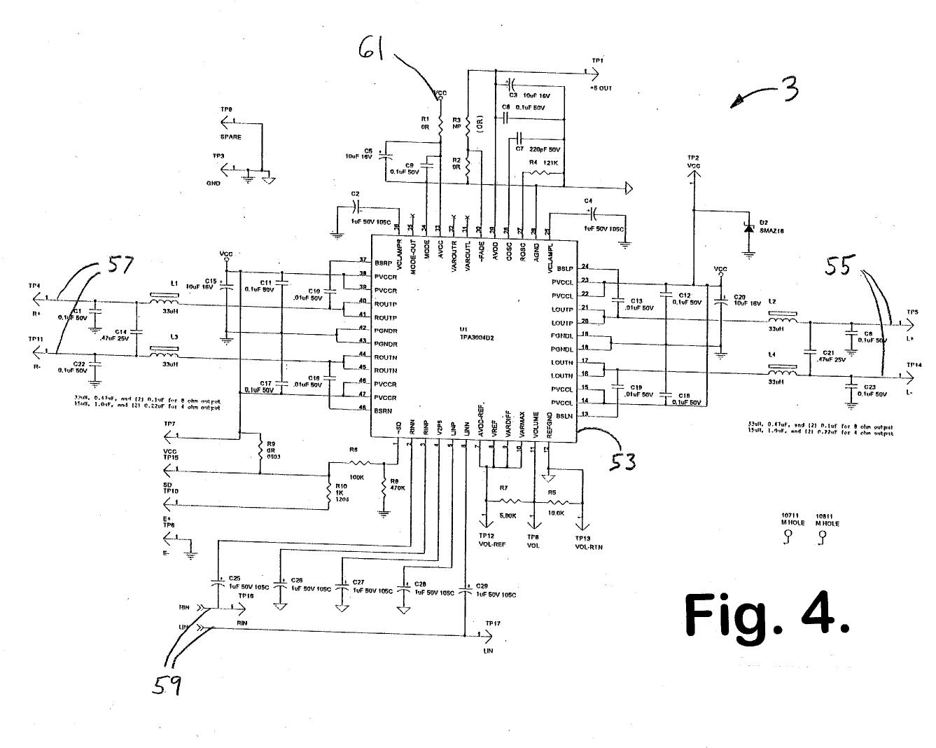

Referring to the drawings in more detail, the reference number 1 generally designates a water bottle audio amplifier unit according to the present invention. As best seen in FIGS. 3 and 4, the unit 1 includes audio amplifier circuitry 3 and a battery or battery pack 5 providing power to the amplifier circuitry 3. The amplifier circuitry 3 and battery 5 are both mounted inside a housing 7 which is sized and shaped to fit into a standard bicycle water bottle cage or holder 9, as shown in FIG. 2.

A water bottle holder 9 is a common accessory for a bicycle and is generally used to hold a bottle of drinking water (not shown). A common location for mounting a water bottle holder 9 is on a frame member 11 of a bicycle, which is located within easy reach of a bicyclist positioned astride the bicycle. It is believed that a common standard diameter for bicycle water bottles is 74 mm (2.9 in) and that the majority of water bottle holders 9 are designed to accept and retain water bottles which are generally cylindrical and have a diameter of somewhere between approximately 2.5 to 3.5 inches.

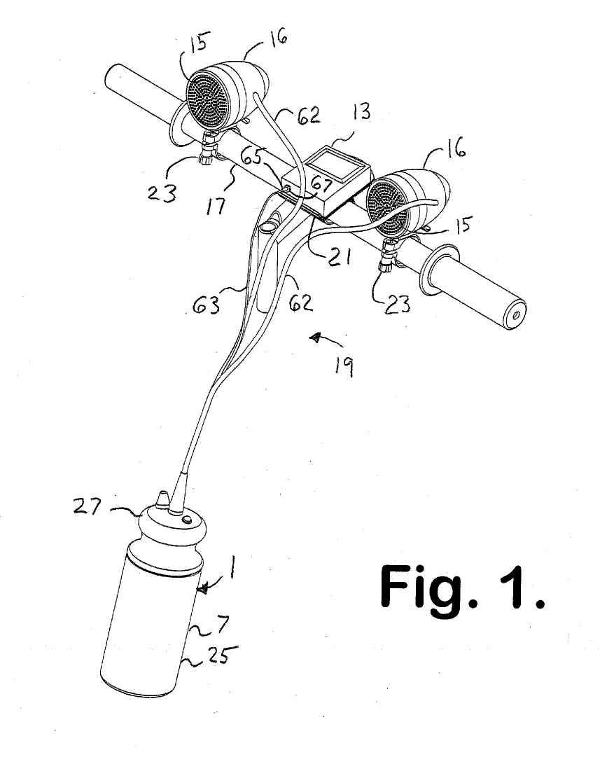

Referring to FIG. 1, the unit 1 is for use with a personal audio device 13 (such as a portable compact disc or tape player, a radio (including a satellite radio), an mp3 player (such as an ipod®), or the like, and a pair of speakers 15, which may be, for example mounted in speaker housings 16 on a handlebar 17 of a bicycle. The unit 1 accepts an audio signal from the personal audio device 13, amplifies the signal, and passes the signal to the speakers 15 where it is emitted as sound. In combination, the personal audio device 13, amplifier unit 1, speakers 15, speaker housings 16, and associated wiring, comprise a bicycle audio system 19. The audio system 19 may also include a mount 21 located on the handlebar 17 for supporting and retaining the personal audio device 13.

The speaker housings 16 and mount 21may be removably mounted on the handlebar 17 using quick-disconnect mounting rings 23 which allow them to be easily removed from the bicycle. Mounting rings 23 of this type are sold by Nite Rider Technical Lighting Systems of San Diego, Calif. The housings 16 each receive, for example, a respective 2 inch speaker 15.

As best seen in FIG. 3, the housing 7 is preferably shaped like a common bicycle water bottle and includes a bottom portion 25 and a top portion 27. The bottom portion 25 includes a generally cylindrical outer wall 29, an open top 31 and closed bottom 33. The outer wall 29 includes an annular upper edge 35 encircling the open top 31 and internal threads 37 are formed in the wall 29 proximate the open top 31. The top portion 27 of the housing 7 forms a closure member for the open top 31 of the bottom portion 25 and includes a downwardly extending cylindrical flange 39 having external threads 41 engageable with the internal threads 37 of the bottom portion 25 to connect the top portion 27 to the bottom portion 25. The downwardly extending cylindrical flange 39 defines an opening 43 into an upper cavity 45 of the housing 7 inside the top portion 27.

A radially outwardly extending annular flange 47 is formed on the top portion 27 above the cylindrical flange 39. An elastomeric sealing gasket 49 is captured between the annular flange 47 and the upper edge 35 of the bottom portion 25 to form a water-tight seal when the top portion 27 is installed onto the bottom portion 25.

The amplifier circuitry 3 is mounted on an integrated circuit board 51 which is sized and shaped to be received within the housing 7, and preferably to be received through the opening 43 such that the circuit board 51 can be positioned inside the upper cavity 45, inside the top portion 27. An example of acceptable amplifier circuitry 3 is shown in FIG. 4 and includes a Texas Instruments® TPA3004D2 12 W stereo audio power amplifier chip 53. It is to be understood, however, that the present invention is not to be limited to any particular amplifier circuitry 3. In general, the circuitry 3 includes speaker outputs 55 and 57 for left and right speakers 15, respectively, as well as signal inputs 59 for receiving an audio signal from the personal audio device 13 and a power input 61 for receiving D.C. (direct current) from the battery 5 (negative to ground).

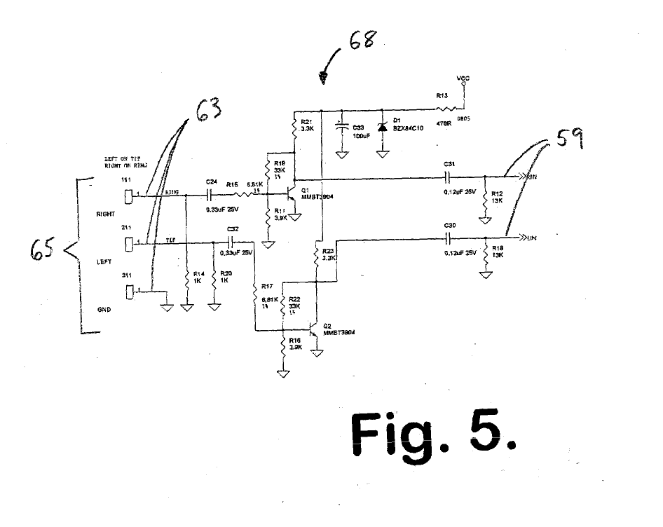

Referring again to FIG. 1, the speaker outputs 55 and 57 are connected to the respective speakers 15 by speaker wiring 62. The signal input 59 receives the audio signal through input wiring 63 having a plug 65 for insertion into a headphone jack 67 of the personal audio device 13. As shown in FIG. 5, the input wiring 63 may be connected to signal processing circuitry 68, which is in turn connected to the signal input 59.

Referring to FIG. 3, the wiring 62 and 63 extends outwardly from the housing 7 through an opening 69. The opening 69 is sealed around the wiring 62 and 63 by a waterproof grommet 71.

The battery 5 comprises a plurality of rechargeable cells 73, which may be, for example, Nickel Cadmium (NiCad) cells. The size and number of cells 73 are selected to meet the power requirements of the circuitry 3. For example, the TPA3004D2 has a supply voltage requirement of 8.5 to 18 volts, and the battery 5 is shown as comprising eleven 1.5 volt cells 73 in series, producing a combined 16.5 volts. The battery 5 is received inside the housing 7 and preferably within the bottom portion 25.

The battery 5 is connected to the power input 61 of the amplifier circuitry 3 by a power lead 75 controlled by an on/off switch 77 extending through the housing 7. A power LED (light emitting diode) 79 visible from outside the housing 7 is energized when the switch 77 is in the on position.

It is to be understood that while certain forms of the present invention have been illustrated and described herein, it is not to be limited to the specific forms or arrangement of parts described and shown. For example, although the amplifier unit 1 has been described and depicted herein as being cylindrical and sized to fit within the most common type of water bottle holder 9 which is designed to receive and retain a cylindrical water bottle, it is to be understood that the present invention could be adapted to fit in most any type of water bottle holder 9 and configured in different geometries.

What is claimed and desired to be secured by Letters Patent is as follows:

1. An audio amplifier unit for a bicycle audio system comprising:
a) a housing sized to be received and retained within a bicycle water bottle holder;
b) audio amplifier circuitry within said housing;
c) a power source within said housing and powering said audio amplifier circuitry; and
d) electrical connections for connecting said amplifier circuitry to a personal audio device and at least one external speaker.

2. The amplifier unit as in claim 1 wherein said housing is generally cylindrical and has a diameter of between 2.5 and 3.5 inches.

3. The amplifier unit as in claim 1 wherein said housing is generally cylindrical and has a diameter of approximately 74 mm.

4. The amplifier unit as in claim 1 wherein said power source is a rechargeable battery.

5. The amplifier unit as in claim 1 wherein said housing has a bottom portion and a top portion removably securable to said bottom portion.

6. The amplifier unit as in claim 5 wherein said power source is contained in said housing bottom portion.

7. The amplifier unit as in claim 6 wherein said amplifier circuitry is contained in said housing top portion.

8. The amplifier unit as in claim 7 wherein said power source is a rechargeable battery.

9. The amplifier unit as in claim 7 wherein said amplifier circuitry is on an integrated circuit board.

10. An audio amplifier unit for a bicycle audio system comprising:
a) a housing sized to be received and retained within a bicycle water bottle holder, said housing having an upper portion and a lower portion removably connected to said lower portion;
b) audio amplifier circuitry positioned within said upper portion of said housing;
c) a rechargeable battery positioned within said lower portion of said housing and powering said audio amplifier circuitry; and
d) electrical connections for connecting said amplifier circuitry to a personal audio device and at least one external speaker.

11. The amplifier unit as in claim 10 wherein said housing is generally cylindrical and has a diameter of between 2.5 and 3.5 inches.

12. The amplifier unit as in claim 10 wherein said housing is generally cylindrical and has a diameter of approximately 74 mm.

13. The amplifier unit as in claim 10 wherein said amplifier circuitry is on an integrated circuit board.

14. An audio amplifier unit for a bicycle audio system comprising:
a) a generally cylindrical housing having a diameter of between 2.5 and 3.5 inches;
b) audio amplifier circuitry within said housing;
c) a power source within said housing and powering said audio amplifier circuitry; and
d) electrical connections for connecting said amplifier circuitry to a personal audio device and at least one external speaker.

15. The amplifier unit as in claim 14 wherein said power source is a rechargeable battery.

16. The amplifier unit as in claim 14 wherein said housing has a bottom portion and a top portion removably securable to said bottom portion.

17. The amplifier unit as in claim 16 wherein said power source is contained in said housing bottom portion.

18. The amplifier unit as in claim 17 wherein said amplifier circuitry is contained in said housing top portion.

19. The amplifier unit as in claim 17 wherein said power source is a rechargeable battery.

20. The amplifier unit as in claim 18 wherein said amplifier circuitry is on an integrated circuit board.
